(19) United States
(12) Patent Application Publication
(10) Pub. No.: US 2026/0341388 A1
(43) Pub. Date: Oct. 29, 2026

(54) Memory device test circuit and memory device test method

(71) Applicant: REALTEK SEMICONDUCTOR CORPORATION, Hsinchu (TW)

(72) Inventors: SHENG-LIN LIN, Hsinchu (TW); Shih-Chieh Lin, Hsinchu (TW)

(21) Appl. No.: 19/650,841

(22) Filed: Apr. 17, 2026

(30) Foreign Application Priority Data
Apr. 25, 2025 (TW) 114115819

(51) Int. Cl. G11C 29/38

(52) U.S. Cl. CPC G11C 29/38

(57) ABSTRACT

A memory device test circuit is used to test a memory device and includes a storage circuit, a comparison circuit, and a control circuit. The storage circuit is used to store a test data. The control circuit is used to execute the following steps to test the memory device: (A) controlling the memory device to enter a first power mode, and then controlling the memory device to exit the first power mode; (B) writing the test data into the memory device; (C) controlling the memory device to enter a second power mode, and then controlling the memory device to exit the second power mode; (D) comparing a stored data in the memory device with the test data.

### BACKGROUND OF THE INVENTION

### 1. Field of the Invention

The present invention generally relates to a memory device, and more particularly, to a memory device test circuit and a memory device test method.

### 2. Description of Related Art

To reduce standby power of a system on a chip (SoC) and maintain a value stored in a memory device, power modes are usually added in the SoC for control. For example, for the memory, the power modes usually include the light sleep (LS) mode, the deep sleep (DS) mode, and the shutdown (SD) mode. In terms of power consumption, the shutdown mode consumes relatively little power, followed by the deep sleep mode, and the light sleep mode consumes relatively much power. The memory can retain data in the light sleep mode and the deep sleep mode, but the memory cannot retain data in the shutdown mode.

Conventional built-in self-test (BIST) circuits require multiple test vectors to test different power modes separately. These test vectors require a separate test process, resulting in complicated and time-consuming testing of the memory device.

### SUMMARY OF THE INVENTION

In view of the issues of the prior art, an object of the present invention is to provide a memory device test circuit and a memory device test method, so as to make an improvement to the prior art.

According to one aspect of the present invention, a memory device test circuit is provided. The memory device test circuit is configured to test a memory device and includes a storage circuit, a comparison circuit, and a control circuit. The storage circuit is configured to store a test data. The comparison circuit is coupled to the storage circuit. The control circuit is coupled to the storage circuit, the comparison circuit, and the memory device, and is configured to execute the following steps to test the memory device: (A) controlling the memory device to enter a first power mode, and then controlling the memory device to exit the first power mode; (B) writing the test data into the memory device; (C) controlling the memory device to enter a second power mode, and then controlling the memory device to exit the second power mode; and (D) comparing a stored data in the memory device with the test data.

According to another aspect of the present invention, a memory device test method is provided. The memory device test method is for testing a memory device and includes the following steps: (A) controlling the memory device to enter a first power mode, then controlling the memory device to exit the first power mode; (B) writing a test data into the memory device; (C) controlling the memory device to enter a second power mode, then controlling the memory device to exit the second power mode; and (D) comparing a stored data in the memory device with the test data.

The technical means embodied in the embodiments of the present invention can solve at least one of the problems of the prior art. Therefore, compared to the prior art, the present invention can simplify the complexity of memory device testing and save test time.

These and other objectives of the present invention no doubt become obvious to those of ordinary skill in the art after reading the following detailed description of the preferred embodiments with reference to the various figures and drawings.

### BRIEF DESCRIPTION OF THE DRAWINGS

FIG. 1 is a functional block diagram of a BIST circuit for a memory device according to an embodiment of the present invention.

FIG. 2A and FIG. 2B are flowcharts of the memory device test method according to an embodiment of the present invention.

FIG. 3 is the timing diagram of the main signals in FIG. 1 according to an embodiment.

FIG. 4 is the timing diagram of the main signals in FIG. 1 according to another embodiment.

FIG. 5 is a flowchart of the error diagnosis method according to an embodiment of the present invention.

FIG. 6 is the timing diagram of the main signals in FIG. 1 according to another embodiment.

### DETAILED DESCRIPTION OF THE EMBODIMENTS

The following description is written by referring to terms of this technical field. If any term is defined in this specification, such term should be interpreted accordingly. In addition, the connection between objects or events in the below-described embodiments can be direct or indirect provided that these embodiments are practicable under such connection. Said “indirect” means that an intermediate object or a physical space exists between the objects, or an intermediate event or a time interval exists between the events.

The disclosure herein includes a memory device test circuit and a memory device test method. On account of that some or all elements of the memory device test circuit could be known, the detail of such elements is omitted provided that such detail has little to do with the features of this disclosure, and that this omission nowhere dissatisfies the specification and enablement requirements. Some or all of the processes of the memory device test method may be implemented by software and/or firmware and can be performed by the memory device test circuit or its equivalent. A person having ordinary skill in the art can choose components or steps equivalent to those described in this specification to carry out the present invention, which means that the scope of this invention is not limited to the embodiments in the specification.

In the following description, signals are active-high, which means that signals are active at high levels and inactive at low levels, and that asserting/de-asserting a signal means setting the signal high/low. This is for the purpose of explanation, not for limiting the scope of the invention. In other words, in an alternative implementation, signals can be active-low, which means that signals are active at low levels and inactive at high levels, and that asserting/de-asserting a signal means setting the signal low/high. A level transition or a logic level transition means that a signal changes from an asserted (active) state to a de-asserted (inactive) state, or from a de-asserted (inactive) state to an asserted (active) state.

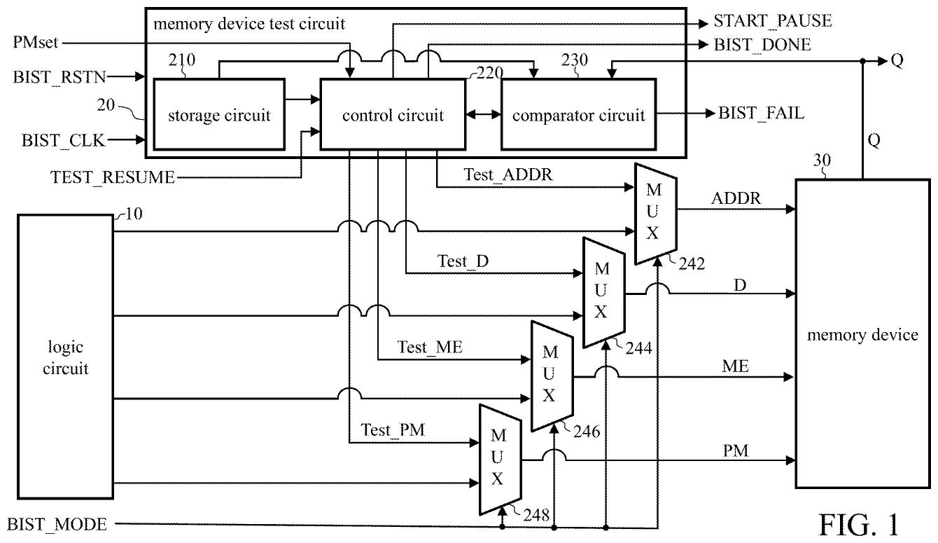

FIG. 1 is a functional block diagram of a BIST circuit for a memory device according to an embodiment of the present invention. The memory device test circuit 20 is coupled to the memory device 30 and is configured to test the memory device 30. The memory device test circuit 20 includes a storage circuit 210, a control circuit 220, and a comparison circuit 230, all of which are coupled to one another. The memory device 30 may be a memory, a retention register, or other components or circuits having data storage capability. The storage circuit 210 stores the test data Test_D (i.e., the test vector, or referred to as the data background).

Under general operation, the logic circuit 10 (which may include the memory device control circuit) controls the memory device 30 through the address signal ADDR, the enable/disable signal ME, and the mode control signal PM. The input data D is data to be written into the memory device 30, and the stored data Q is data read out from the memory device 30.

In the test mode, the control circuit 220 of the memory device test circuit 20 controls or operates the memory device 30 through the address signal Test_ADDR, the enable/disable signal Test_ME, and the mode control signal Test_PM. When the memory device 30 is enabled, it can be accessed (read and/or written). When the memory device 30 is disabled, it cannot be accessed. The mode control signal PM and the mode control signal Test_PM can not only control the memory device 30 to enter a power mode, but can further control the memory device 30 to enter different kinds of power modes: a light sleep mode, a deep sleep mode, or a shutdown mode. The control circuit 220 generates the mode control signal Test_PM according to the mode setting signal PMset. In some embodiments, a user can change the mode setting signal PMset through a configurable register.

The test start signal BIST_MODE controls the multiplexer (MUX) 242, the multiplexer 244, the multiplexer 246, and the multiplexer 248 to output a signal generated by the logic circuit 10 or a signal generated by the memory device test circuit 20, that is, determines whether the memory device 30 is controlled by the logic circuit 10 (i.e., the normal operation) or controlled by the control circuit 220 (i.e., the test mode). The clock BIST_CLK is the clock that the memory device test circuit 20 provides to the memory device 30 when testing the memory device 30. The reset signal BIST_RSTN is used to reset the memory device test circuit 20.

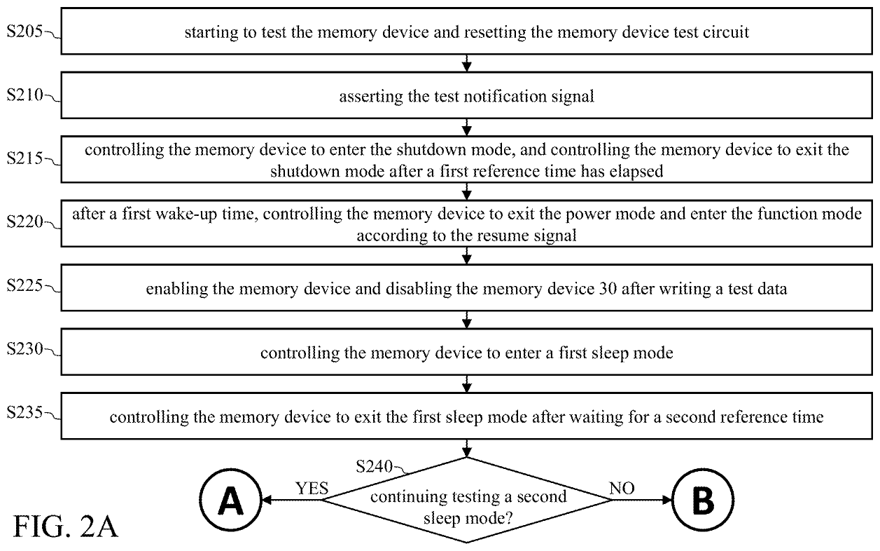

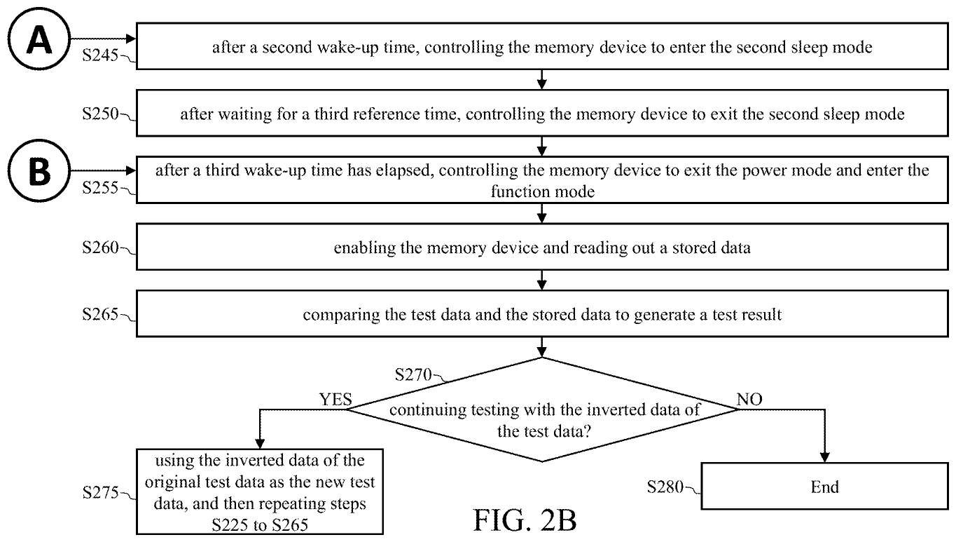

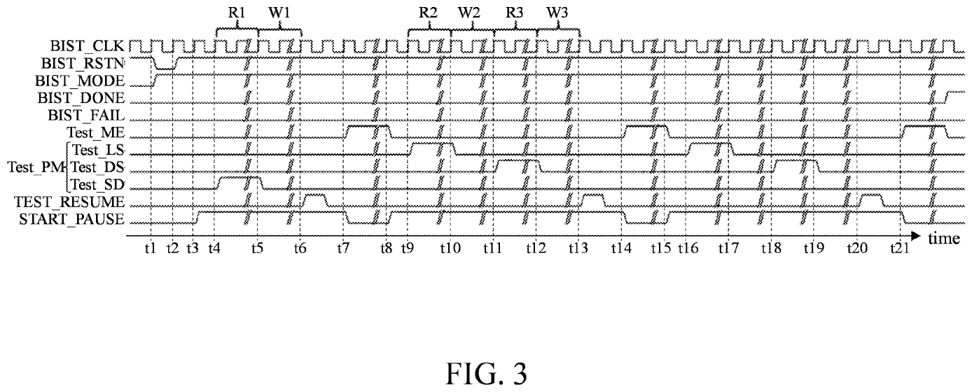

FIG. 2A and FIG. 2B are flowcharts of the memory device test method according to an embodiment of the present invention. FIG. 3 is a timing diagram of main signals in FIG. 1 according to an embodiment, wherein the mode control signal Test_PM includes a light sleep mode control signal Test_LS (corresponding to the light sleep mode), a deep sleep mode control signal Test_DS (corresponding to the deep sleep mode), and a shutdown mode control signal Test_SD (corresponding to the shutdown mode). For example, when the user sets the mode setting signal PMset to {1, 0, 1}, the memory device test circuit 20 tests the light sleep mode and the shutdown mode. When the user sets the mode setting signal PMset to {0, 1, 1}, the memory device test circuit 20 tests the deep sleep mode and the shutdown mode. When the user sets the mode setting signal PMset to {1, 1, 1}, the memory device test circuit 20 tests three power modes.

The memory device test method of the present invention is discussed below with reference to FIG. 2A, FIG. 2B, and FIG. 3. FIGS. 2A and 2B include the following steps.

Step S205: Starting to test the memory device 30 by asserting the test start signal BIST_MODE (at the time point t1), and resetting the memory device test circuit 20 by asserting the reset signal BIST_RSTN.

Step S210: The control circuit 220 asserts the test notification signal START_PAUSE to notify the user that the memory device 30 is about to enter the power mode (at the time point t3).

Step S215: The control circuit 220 controls the memory device 30 to enter the shutdown mode (at the time point t4), and after the first reference time R1 has elapsed, the control circuit 220 controls the memory device 30 to exit the shutdown mode (at the time point t5).

Step S220: After the first wake-up time W1, the control circuit 220 controls the memory device 30 to exit the power mode and enter the function mode (at the time point t6) according to the resume signal TEST_RESUME input by the user. In response to the assertion of the resume signal TEST_RESUME at the time point t6, the control circuit 220 de-asserts the test notification signal START_PAUSE at the time point t7 to notify the user that the memory device 30 has exited the power mode.

Step S225: The control circuit 220 enables the memory device 30 via the enable/disable signal Test_ME (at the time point t7) to write the test data Test_D, disables the memory device 30 after writing the test data Test_D, and asserts the test notification signal START_PAUSE to notify the user that the memory device 30 is about to enter the power mode (at the time point t8). At this time point, the memory device 30 stores the test data Test_D.

Step S230: The control circuit 220 controls the memory device 30 to enter a first sleep mode (i.e., one of the light sleep mode and the deep sleep mode; in the example of FIG. 3, the first sleep mode is the light sleep mode) through the light sleep mode control signal Test_LS or the deep sleep mode control signal Test_DS (at the time point t9).

Step S235: The control circuit 220 controls the memory device 30 to exit the first sleep mode (at the time point t10) after waiting for the second reference time R2.

Step S240: The control circuit 220 determines whether to continue testing the second sleep mode. If YES, then the flow proceeds to step S245; otherwise, the flow proceeds to step S255.

Step S245: After the second wake-up time W2, the control circuit 220 controls, through the light sleep mode control signal Test_LS or the deep sleep mode control signal Test_DS, the memory device 30 to enter the second sleep mode (in the example of FIG. 3, the second sleep mode is the deep sleep mode) (at the time point t11).

Step S250: After waiting for the third reference time R3, the control circuit 220 controls the memory device 30 to exit the second sleep mode (at the time point t12).

Step S255: After the third wake-up time W3 has elapsed, the memory device test circuit 20 controls the memory device 30 to exit the power mode and enter the function mode according to the resume signal TEST_RESUME input by the user (at the time point t13). In response to the assertion of the resume signal TEST_RESUME at the time point t13, the control circuit 220 de-asserts the test notification signal START_PAUSE at the time point t14 to notify the user that the memory device 30 has exited the power mode.

Step S260: The control circuit 220 enables the memory device 30 through the enable/disable signal Test_ME (at the time point t14) and reads out the stored data Q from the memory device 30.

Step S265: The control circuit 220 controls the comparison circuit 230 to compare the test data Test_D and the stored data Q to generate the test result BIST_FAIL. When the test data Test_D is equal to the stored data Q, the memory device 30 passes the test (the test result BIST_FAIL is at a low level). Conversely, when the test data Test_D is not equal to the stored data Q, the memory device 30 has failed the test (the test result BIST_FAIL is at a high level, indicating that the memory device 30 cannot correctly return from the power mode to the function mode).

Step S270: The control circuit 220 determines whether to continue testing with the inverted data of the test data Test_D. If YES, then the flow proceeds to step S275; otherwise, the flow proceeds to step S280. Logic 1 and Logic 0 are the inverted data of each other.

Step S275: The control circuit 220 uses the inverted data of the original test data Test_D as the new test data Test_D, and then repeats steps S225 to S265 (refer to the time points t14 to t21 in FIG. 3, which respectively correspond to the time points t7 to t14). For example, if “1010 . . . 1010” is written when step S225 is performed for the first time, then “0101 . . . 0101” is written when step S225 is performed for the second time.

Step S280: The memory device test circuit 20 asserts the test end signal BIST_DONE to indicate the end of the test.

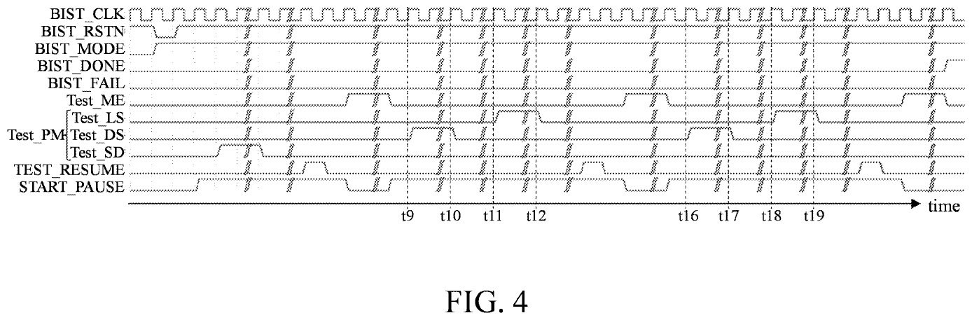

Reference is made to FIG. 4, which is a timing diagram of the main signals in FIG. 1 according to another embodiment. In the embodiment of FIG. 4, the first sleep mode of step S230 and the second sleep mode of step S245 respectively correspond to the deep sleep mode (between the time points t9 and t10 and between the time points t16 and t17) and the light sleep mode (between the time points t11 and t12 and between the time points t18 and t19).

It should be noted that, when step S245 and step S255 are skipped (i.e., when step S240 is NO), the time points t10 and t12 in FIGS. 3 and 4 become the same time point, and the time points t17 and t19 become the same time point.

In summary, the memory device test circuit 20 of the present invention uses a single test vector (i.e., in a single test process) to test two power modes (i.e., the shutdown mode and the light sleep mode or the deep sleep mode, steps S215 to S240 and steps S255 to S265) or three power modes (i.e., the shutdown mode, the light sleep mode, and the deep sleep mode, steps S215 to S265), which not only simplifies the complexity of the memory device test but also saves the test time.

In some embodiments, steps S215 to S220 of FIG. 2A may be omitted (i.e., the shutdown mode is not tested), but the second sleep mode is tested (YES at step S240). In this way, two power modes (i.e., the light sleep mode and the deep sleep mode) can also be tested in a single test process.

The lengths of the first reference time R1, the first wake-up time W1, the second reference time R2, the second wake-up time W2, the third reference time R3, and the third wake-up time W3 are related to the design of the memory device 30, the application method of the memory device 30, and/or the test requirements of the memory device 30, and can be set by the user (e.g., through writing register(s)). In addition, the user can modify the memory device test circuit 20 to control the memory device 30 to enter the power mode during a period when the test notification signal START_PAUSE is at a high level (e.g., between the time points t3 and t7, between the time points t8 and t14, and between the time points t15 and t21 in FIG. 3), thereby allowing the user to flexibly adjust the lengths of the test notification signal START_PAUSE, the first wake-up time W1, the second wake-up time W2, and the third wake-up time W3.

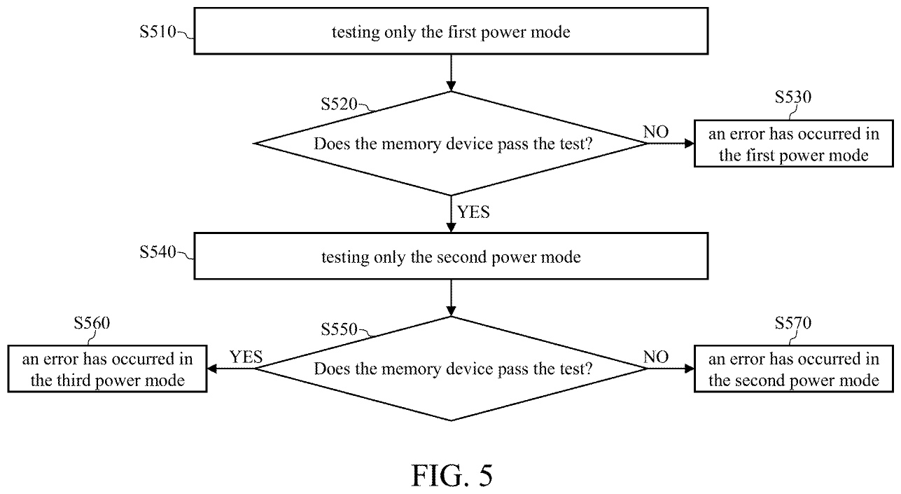

Reference is made to FIG. 5, which is a flowchart of the error diagnosis method according to an embodiment of the present invention. When the test result BIST_FAIL of step S265 in FIG. 2B indicates that the memory device 30 has failed the test, the memory device test circuit 20 can further execute the flow of FIG. 5 to confirm whether an error has occurred in the shutdown mode, the light sleep mode, or the deep sleep mode.

First, the memory device test circuit 20 tests only the first power mode of the memory device 30 (step S510). When the test result BIST_FAIL indicates that the memory device 30 has failed the test (NO at step S520), it can be concluded that an error has occurred in the first power mode of the memory device 30 (step S530). When the test result BIST_FAIL indicates that the memory device 30 passes the test (YES at step S520), the memory device test circuit 20 next tests only the second power mode of the memory device 30 (step S540). When the test result BIST_FAIL indicates that the memory device 30 has failed the test (NO at step S550), it can be concluded that an error has occurred in the second power mode of the memory device 30 (step S570); otherwise (NO at step S550), it can be concluded that an error has occurred in the third power mode of the memory device 30 (step S560).

The first, second, and third power modes in FIG. 5 may be a permutation and combination of the light sleep mode, the deep sleep mode, and the shutdown mode. For example, the first, second, and third power modes can respectively be the light sleep mode, the deep sleep mode, and the shutdown mode, or the shutdown mode, the light sleep mode, and the deep sleep mode.

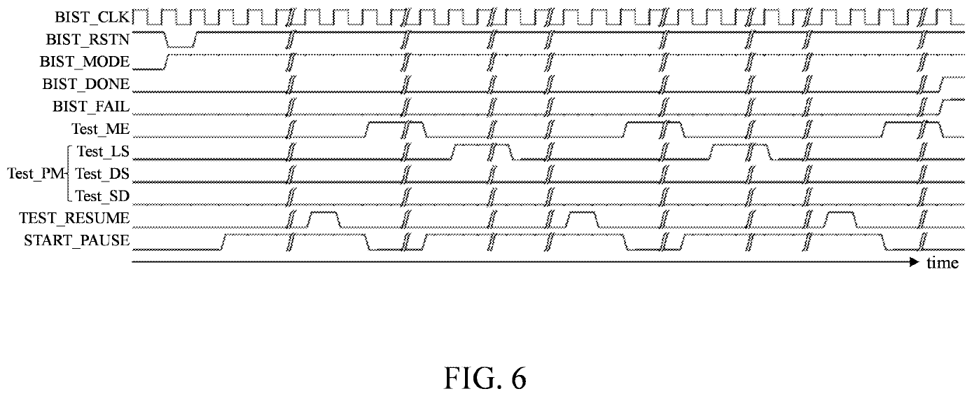

Reference is made to FIG. 6, which is the timing diagram of the main signals in FIG. 1 according to another embodiment. The example of FIG. 6 corresponds to testing only the light sleep mode of the memory device 30. Of the mode control signal Test_PM, only the light sleep mode control signal Test_LS has a level transition, while the deep sleep mode control signal Test_DS and the shutdown mode control signal Test_SD both remain at the low level during the test. People having ordinary skill in the art can generate the mode control signal Test_PM that corresponds to testing only the deep sleep mode and only the shutdown mode according to FIG. 6.

The light sleep mode, the deep sleep mode, and the shutdown mode are intended to illustrate the invention by way of example and not to limit the scope of the claimed invention. People having ordinary skill in the art may apply the present invention to other types of power modes in accordance with the foregoing discussions.

Various functional components or blocks have been described herein. As appreciated by persons skilled in the art, in some embodiments, the functional blocks can preferably be implemented through circuits (either dedicated circuits, or general purpose circuits, which operate under the control of one or more processors and coded instructions), which typically comprise transistors or other circuit elements that are configured in such a way as to control the operation of the circuitry in accordance with the functions and operations described herein. As further appreciated by persons skilled in the art, the specific structure or interconnections of the circuit elements can typically be determined by a compiler, such as a register transfer language (RTL) compiler. RTL compilers operate upon scripts that closely resemble assembly language code, to compile the script into a form that is used for the layout or fabrication of the ultimate circuitry. Indeed, RTL is well known for its role and use in the facilitation of the design process of electronic and digital systems.

Since a person having ordinary skill in the art can appreciate the implementation detail and the modification thereto of the present method invention through the disclosure of the device invention, repeated and redundant description is thus omitted. Note that the shape, size, and ratio of any element in the disclosed figures are exemplary for understanding, not for limiting the scope of this invention. Furthermore, there is no step sequence limitation for the method inventions as long as the execution of each step is applicable. In some instances, the steps can be performed simultaneously or partially simultaneously.

The aforementioned descriptions represent merely the preferred embodiments of the present invention, without any intention to limit the scope of the present invention thereto. Various equivalent changes, alterations, or modifications based on the claims of the present invention are all consequently viewed as being embraced by the scope of the present invention.

What is claimed is:

1. A memory device test circuit configured to test a memory device, comprising:
a storage circuit configured to store a test data;
a comparison circuit coupled to the storage circuit;
a control circuit coupled to the storage circuit, the comparison circuit, and the memory device, and configured to execute following steps to test the memory device:
(A) controlling the memory device to enter a first power mode, then controlling the memory device to exit the first power mode;
(B) writing the test data into the memory device;
(C) controlling the memory device to enter a second power mode, then controlling the memory device to exit the second power mode; and
(D) comparing a stored data in the memory device with the test data.

2. The memory device test circuit of claim 1, wherein the first power mode is a shutdown mode, the second power mode is a light sleep mode, step (A) precedes step (B), and step (B) precedes step (C).

3. The memory device test circuit of claim 1, wherein the first power mode is a shutdown mode, the second power mode is a deep sleep mode, step (A) precedes step (B), and step (B) precedes step (C).

4. The memory device test circuit of claim 3, wherein the control circuit further
performs following steps:
(E) controlling the memory device to enter a light sleep mode, then controlling the memory device to exit the light sleep mode;
wherein step (B) precedes step (E).

5. The memory device test circuit of claim 4, wherein step (C) precedes step (E).

6. The memory device test circuit of claim 4, wherein step (E) precedes step (C).

7. The memory device test circuit of claim 1, wherein the first power mode is a deep sleep mode, the second power mode is a light sleep mode, and step (B) precedes step (A) and step (C).

8. The memory device test circuit of claim 7, wherein step (A) precedes step (C).

9. The memory device test circuit of claim 7, wherein step (C) precedes step (A).

10. The memory device test circuit of claim 1, wherein step (A) to step (D) are executed in a single test process.

11. A memory device test method for testing a memory device, comprising following steps:
(A) controlling the memory device to enter a first power mode, then controlling the memory device to exit the first power mode;
(B) writing a test data into the memory device;
(C) controlling the memory device to enter a second power mode, then controlling the memory device to exit the second power mode; and
(D) comparing a stored data in the memory device with the test data.

12. The method of claim 11, wherein the first power mode is a shutdown mode, the second power mode is a light sleep mode, step (A) precedes step (B), and step (B) precedes step (C).

13. The method of claim 11, wherein the first power mode is a shutdown mode, the second power mode is a deep sleep mode, step (A) precedes step (B), and step (B) precedes step (C).

14. The method of claim 13 further comprising:
(E) controlling the memory device to enter a light sleep mode, then controlling the memory device to exit the light sleep mode;
wherein step (B) precedes step (E).

15. The method of claim 14, wherein step (C) precedes step (E).

16. The method of claim 14, wherein step (E) precedes step (C).

17. The method of claim 11, wherein the first power mode is a deep sleep mode, the second power mode is a light sleep mode, and step (B) precedes step (A) and step (C).

18. The method of claim 17, wherein step (A) precedes step (C).

19. The method of claim 17, wherein step (C) precedes step (A).

20. The method of claim 11, wherein step (A) to step (D) are executed in a single test process.
